(19) United States
(12) Patent Application Publication
(10) Pub. No.: US 2024/0258385 A1
(43) Pub. Date: Aug. 1, 2024

(54) GALLIUM NITRIDE BIDIRECTIONAL SWITCH DEVICE

(71) Applicant: HUNAN SAN'AN SEMICONDUCTOR CO., LTD., Changsha (CN)

(72) Inventors: Zhidong LIN, Changsha (CN); Cheng LIU, Changsha (CN); Ning XU, Changsha (CN); Nien-tze YEH, Changsha (CN); Danni YAN, Changsha (CN); Han XU, Changsha (CN)

(21) Appl. No.: 18/613,276

(22) Filed: Mar. 22, 2024

Related U.S. Application Data
(63) Continuation of application No. PCT/CN2022/118733, filed on Sep. 14, 2022.

(30) Foreign Application Priority Data
Sep. 30, 2021 (CN) 2021111606814

(51) Int. Cl. H01L 29/40; H01L 29/20; H01L 29/66; H01L 29/778

(52) U.S. Cl. CPC H01L 29/407; H01L 29/404; H01L 29/66462; H01L 29/7786; H01L 29/2003

(57) ABSTRACT

A gallium nitride bidirectional switch device includes: a substrate, a semiconductor epitaxial layer and a first-level field plate dielectric layer sequentially stacked in that order; the semiconductor epitaxial layer is provided with an active area and a non-active area, the first-level field plate dielectric layer is located in the active area and extends to the non-active area, a groove penetrates the first-level field plate dielectric layer and the semiconductor epitaxial layer to expose the substrate and is located in the non-active area, two first-level field plate metals are spaced on the first-level field plate dielectric layer and located in the active area; and the two first-level field plate metals are connected through a first interconnecting metal to form a first field plate metal interconnecting structure, and a part of the first field plate metal interconnecting structure fills the groove and is connected with the substrate exposed by the groove.

### TECHNICAL FIELD

The disclosure relates to the field of semiconductor devices, and more particularly to a gallium nitride (GaN) bidirectional switch device.

### BACKGROUND

As a power conversion device for AC-AC (alternating current-alternating current) conversion, a matrix converter can achieve high AC-AC conversion efficiency by using bidirectional switches that can operate in four quadrants. Compared with a traditional AC-DC-AC (alternating current-direct current-alternating current) indirect conversion mode, the matrix converter does not need to be externally connected with capacitors with large capacitance or inductors with large inductance, and at the same time reduces the number of components in circuits and the number of connecting lines among the components, thus reducing system volume, weakening parasitic effects and improving system reliability.

At present, in the matrix converter, a common bidirectional switch with reverse blocking ability usually adopts two insulated gate bipolar transistors (IGBT) in reverse parallel, and each IGBT is connected in series with a diode. However, using this method requires a combination of multiple power devices, which increases the area and cost of chips in power integrated circuits, increases device loss and reduces device performance. At the same time, when the matrix converter is in an off state, electric field distribution in a withstand voltage region is uneven.

### SUMMARY

The disclosure aims to provide a GaN bidirectional switch device, which can reduce device volume, make electric field distribution in a withstand voltage region more uniform when the GaN bidirectional switch device is in an off state, and improve a withstand voltage of the GaN bidirectional switch device.

An embodiment of the disclosure provides a GaN bidirectional switch device, including: a substrate, a semiconductor epitaxial layer, a first-level field plate dielectric layer, a groove, a first first-level field plate metal and a second first-level field plate metal. The semiconductor epitaxial layer is disposed on the substrate, and the semiconductor epitaxial layer is provided with an active area and a non-active area located outside the active area. The first-level field plate dielectric layer is disposed on a side of the semiconductor epitaxial layer facing away from the substrate, and is located in the active area and extends to the non-active area. The groove penetrates the first-level field plate dielectric layer and the semiconductor epitaxial layer to expose a part of the substrate, and the groove is located in the non-active area. The first first-level field plate metal and the second first-level field plate metal are spaced on a side of the first-level field plate dielectric layer facing away from the semiconductor epitaxial layer and located in the active area, the first first-level field plate metal and the second first-level field plate metal are connected through a first interconnecting metal to form a first field plate metal interconnecting structure, and a part of the first field plate metal interconnecting structure is filled in the groove and is connected with the part of the substrate exposed by the groove.

The disclosure has the following beneficial effects.

A GaN bidirectional switch device provided by the disclosure includes a substrate, a semiconductor epitaxial layer and a first-level field plate dielectric layer sequentially formed in that order; the semiconductor epitaxial layer is provided with an active area and a non-active area located outside the active area, a groove is located in the non-active area and penetrates the first-level field plate dielectric layer and the semiconductor epitaxial layer to expose a part of the substrate, a first first-level field plate metal and a second first-level field plate metal are spaced on a side of the first-level field plate dielectric layer facing away from the semiconductor epitaxial layer and located in the active area, the first first-level field plate metal and the second first-level field plate metal are connected through a first interconnecting metal to form a first field plate metal interconnecting structure, and a part of the first field plate metal interconnecting structure is filled in the groove and is connected with the part of the substrate exposed by the groove; thus the GaN bidirectional switch device provided by the disclosure can avoid using too many power devices and reduce volume of the GaN bidirectional switch device. In addition, on the one hand, the GaN bidirectional switch device has functioning field plates at any time during an AC signal cycle when in an off state, so as to make the electric field distribution in the withstand voltage region more uniform, thereby improving the withstand voltage of the GaN bidirectional switch device, on the other hand, the GaN bidirectional switch device can also inhibit capture of electrons in channels by defects on a surface or in an interior of the semiconductor epitaxial layer under the action of a high electric field during switching of the GaN bidirectional switch device from the off state to the on state, so that the on-resistance of the GaN bidirectional switch device in the on state increases, i.e., inhibiting the phenomenon of current collapse, and thus improving the stability of the GaN bidirectional switch device.

### BRIEF DESCRIPTION OF DRAWINGS

In order to explain technical schemes of embodiments of the disclosure more clearly, the following drawings will be briefly introduced. It should be understood that the following drawings only show some of the embodiments of the disclosure, so they should not be regarded as limiting the scope. For those skilled in the art, other related drawings can be obtained according to these drawings without creative work.

FIG. 1 illustrates a partial structural schematic diagram of a GaN bidirectional switch device according to a first embodiment of the disclosure.

FIG. 2 illustrates a partial structural schematic diagram of the GaN bidirectional switch device according to the first embodiment of the disclosure.

FIG. 3 illustrates a partial structural schematic diagram of the GaN bidirectional switch device according to the first embodiment of the disclosure.

FIG. 4 illustrates a partial structural schematic diagram of another GaN bidirectional switch device according to the first embodiment of the disclosure.

FIG. 5 illustrates a partial structural schematic diagram of another GaN bidirectional switch device according to the first embodiment of the disclosure.

FIG. 6 illustrates a partial structural schematic diagram of a GaN bidirectional switch device according to a second embodiment of the disclosure.

FIG. 7 illustrates a partial structural schematic diagram of another GaN bidirectional switch device according to the second embodiment of the disclosure.

FIG. 8 illustrates a partial structural schematic diagram of another GaN bidirectional switch device according to the second embodiment of the disclosure.

FIG. 9 illustrates a partial structural schematic diagram of a GaN bidirectional switch device according to a third embodiment of the disclosure.

FIG. 10 illustrates a partial structural schematic diagram of the GaN bidirectional switch device according to the third embodiment of the disclosure.

FIG. 11 illustrates a cross-sectional schematic diagram of the GaN bidirectional switch device illustrated in FIG. 10 along an A-A direction.

FIG. 12 illustrates a partial structural schematic diagram of another GaN bidirectional switch device according to the third embodiment of the disclosure.

FIG. 13 illustrates a cross-sectional schematic diagram of the GaN bidirectional switch device illustrated in FIG. 12 along a B-B direction.

FIG. 14 illustrates a cross-sectional schematic diagram of the GaN bidirectional switch device illustrated in FIG. 12 along a C-C direction.

FIG. 15 illustrates a partial structural schematic diagram of a GaN bidirectional switch device according to a fourth embodiment of the disclosure.

FIG. 16 illustrates a schematic circuit diagram of the GaN bidirectional switch device according to the fourth embodiment of the disclosure.

FIG. 17 illustrates a schematic diagram of a working state of the GaN bidirectional switch device according to the fourth embodiment of the disclosure.

FIG. 18 illustrates a first schematic state diagram of a GaN bidirectional switch device according to a fifth embodiment of the disclosure.

FIG. 19 illustrates a second schematic state diagram of the GaN bidirectional switch device according to the fifth embodiment of the disclosure.

FIG. 20 illustrates a third schematic state diagram of the GaN bidirectional switch device according to the fifth embodiment of the disclosure.

FIG. 21 illustrates a fourth schematic state diagram of the GaN bidirectional switch device according to the fifth embodiment of the disclosure.

FIG. 22 illustrates a fifth schematic state diagram of the GaN bidirectional switch device according to the fifth embodiment of the disclosure.

FIG. 23 illustrates a schematic flowchart of a method for preparing a GaN bidirectional switch device according to the fifth embodiment of the disclosure.

### DESCRIPTION OF REFERENCE NUMERALS

10—substrate; 100—semiconductor epitaxial layer; 20—buffer layer; 30—channel layer; 40—barrier layer; 51—first electrode; 52—second electrode; 60—P-type nitride layer; 70—gate electrode; 81—first-level field plate dielectric layer; 811—groove; 82—second-level field plate dielectric layer; 83—third-level field plate dielectric layer; 831—first through-hole; 832—first metal; 91—first-level field plate metal; 91L—first interconnecting metal; 92—second-level field plate metal; 92L—second interconnecting metal; 93—third-level field plate metal; 93L—third interconnecting metal; 94—fourth-level field plate dielectric layer; 941—second through-hole; 942—second metal; 95—insulating layer.

### DETAILED DESCRIPTION OF EMBODIMENTS

In order to make purposes, technical schemes and advantages of embodiments of the disclosure clearer, the technical schemes in the embodiments of the disclosure will be described clearly and completely with the attached drawings. Apparently, the described embodiments are some of the embodiments of the disclosure, but not all the embodiments. Components of the embodiments of the disclosure generally described and illustrated in the drawings herein can be arranged and designed in various different configurations.

Therefore, the following detailed description of the embodiments of the disclosure provided in the accompanying drawings is not intended to limit the scope of the disclosure for which protection is claimed, but merely represents selected embodiments of the disclosure. Based on the embodiments in the disclosure, all other embodiments obtained by those skilled in the art without creative work belong to the scope of protection of the disclosure.

It should be noted that similar labels and letters indicate similar items in the following accompanying drawings, so that once an item is defined in one accompanying drawing, it does not need to be further defined and explained in subsequent accompanying drawings.

In the description of the disclosure, it is noted that the terms “center”, “up”, “down”, “left”, “right”, “inside”, “outside”, etc. indicate an orientation or positional relationship based on the orientation or positional relationship shown in the accompanying drawings, or an orientation or positional relationship in which the product of the disclosure is customarily placed when used, and are intended only for the convenience of describing the disclosure and for simplifying the description, and are not intended to indicate or imply that the device or component referred to must be of a particular orientation, constructed and operated in a particular orientation, and therefore cannot be understood as a limitation on the disclosure. Furthermore, the terms “first”, “second”, “third”, etc. are used to distinguish descriptions and cannot be understood as indicating or implying relative importance.

An embodiment of the disclosure provides a GaN bidirectional switch device, including:
a substrate;
a semiconductor epitaxial layer, disposed on the substrate; and the semiconductor epitaxial layer being provided with an active area and a non-active area located outside the active area;
a first-level field plate dielectric layer, disposed on a side of the semiconductor epitaxial layer facing away from the substrate; and the first-level field plate dielectric layer being located in the active area and extending to the non-active area;
a groove, penetrating the first-level field plate dielectric layer and the semiconductor epitaxial layer to expose a part of the substrate; and the groove being located in the non-active area; and
a first first-level field plate metal and a second first-level field plate metal, spaced on a side of the first-level field plate dielectric layer facing away from the semiconductor epitaxial layer and located in the active area; and
the first first-level field plate metal and the second first-level field plate metal are connected through a first interconnecting metal to form a first field plate metal interconnecting structure, and a part of the first field plate metal interconnecting structure is filled in the groove and is connected with the part of the substrate exposed by the groove.

In an embodiment of the disclosure, the GaN bidirectional switch device further includes:
a first electrode and a second electrode, located in the active area and spaced on the side of the semiconductor epitaxial layer facing away from the substrate; and
a first gate electrode and a second gate electrode, located in the active area and spaced on the side of the semiconductor epitaxial layer facing away from the substrate;
the first gate electrode and the second gate electrode are symmetrically arranged between the first electrode and the second electrode;
the first-level field plate dielectric layer covers the first electrode, the second electrode, the first gate electrode and the second gate electrode and exposes a part of the first electrode, a part of the second electrode, a part of the first gate electrode and a part of the second gate electrode; and
the first first-level field plate metal and the second first-level field plate metal are symmetrically arranged between the first gate electrode and the second gate electrode.

In an embodiment of the disclosure, a part of the first-level field plate dielectric layer extends into the groove to act as an insulating layer, and the insulating layer is disposed between a sidewall of the groove and the part of the first field plate metal interconnecting structure filled in the groove.

In an embodiment of the disclosure, the GaN bidirectional switch device further includes: an insulating layer, disposed between a sidewall of the groove and the part of the first field plate metal interconnecting structure filled in the groove.

In an embodiment of the disclosure, the semiconductor epitaxial layer includes:
a buffer layer, disposed on the substrate;
a channel layer, disposed on a side of the buffer layer facing away from the substrate; and
a barrier layer, disposed on a side of the channel layer facing away from the buffer layer;
the first electrode, the second electrode, the first gate electrode, the second gate electrode and the first-level field plate dielectric layer are disposed on a side of the barrier layer facing away from the channel layer.

In an embodiment of the disclosure, the GaN bidirectional switch device further includes: a first P-type nitride layer and a second P-type nitride layer; and the first P-type nitride layer is disposed between the first gate electrode and the semiconductor epitaxial layer, and the second P-type nitride layer is disposed between the second gate electrode and the semiconductor epitaxial layer.

In an embodiment of the disclosure, a part of the first interconnecting metal of the first field plate metal interconnecting structure is filled in the groove and is in direct contact with the part of the substrate exposed by the groove.

In an embodiment of the disclosure, the groove includes: a first groove and a second groove; the first groove is closer to the first first-level field plate metal than the second groove, and the second groove is closer to the second first-level field plate metal than the first groove, and a part of the first first-level field plate metal of the first field plate metal interconnecting structure is filled in the first groove and is in direct contact with a part of the substrate exposed by the first groove.

In an embodiment of the disclosure, a part of the second first-level field plate metal of the first field plate metal interconnecting structure is filled in the second groove and is in direct contact with a part of the substrate exposed by the second groove.

In an embodiment of the disclosure, the GaN bidirectional switch device further includes:

a second-level field plate dielectric layer, disposed on a side of the first-level field plate dielectric layer facing away from the semiconductor epitaxial layer and located between the first first-level field plate metal and the second first-level field plate metal.

In an embodiment of the disclosure, the GaN bidirectional switch device further includes:
a first second-level field plate metal, disposed on a side of the first first-level field plate metal facing away from the first-level field plate dielectric layer and connected with the first first-level field plate metal;
a second second-level field plate metal, disposed on a side of the second first-level field plate metal facing away from the first-level field plate dielectric layer and connected with the second first-level field plate metal; and
a second interconnecting metal, connected with the first and second second-level field plate metals to form a second field plate metal interconnecting structure.

In an embodiment of the disclosure, a part of the second field plate metal interconnecting structure is filled in the groove.

In an embodiment of the disclosure, the part of the second field plate metal interconnecting structure filled in the groove is disposed on a side of the part of the first field plate metal interconnecting structure filled in the groove facing away from the substrate and is not in contact with the substrate.

In an embodiment of the disclosure, the part of the second field plate metal interconnecting structure filled in the groove is disposed on a side of the part of the first field plate metal interconnecting structure filled in the groove facing away from a sidewall of the groove, and is in direct contact with the substrate.

In an embodiment of the disclosure, the GaN bidirectional switch device further includes:
a third-level field plate dielectric layer, disposed on the first-level field plate dielectric layer and covering the second-level field plate dielectric layer, the first first-level field plate metal, the second first-level field plate metal, the first second-level field plate metal and the second second-level field plate metal.

In an embodiment of the disclosure, the GaN bidirectional switch device further includes:
a first third-level field plate metal, disposed on a side of the third-level field plate dielectric layer facing away from the first-level field plate dielectric layer and connected with the first second-level field plate metal;
a second third-level field plate metal, disposed on the side of the third-level field plate dielectric layer facing away from the first-level field plate dielectric layer and connected with the second second-level field plate metal; and
a third interconnecting metal, connected with the first and second third-level field plate metals to form a third field plate metal interconnecting structure.

In an embodiment of the disclosure, a part of the third field plate metal interconnecting structure is filled in the groove.

In an embodiment of the disclosure, the part of the third field plate metal interconnecting structure filled in the groove is disposed on a side of the part of the second field plate metal interconnecting structure filled in the groove facing away from the part of the first field plate metal interconnecting structure filled in the groove, and is not in contact with the substrate.

In an embodiment of the disclosure, the part of the third field plate metal interconnecting structure filled in the groove is disposed between the part of the second field plate metal interconnecting structure filled in the groove and a sidewall of the groove, and is in direct contact with the substrate.

In an embodiment of the disclosure, the GaN bidirectional switch device further includes:
a fourth-level field plate dielectric layer, disposed on a side of the third-level field plate dielectric layer facing away from the first-level field plate dielectric layer and covering the first third-level field plate metal and the second third-level field plate metal.

Next, the GaN bidirectional switch device provided by the disclosure will be described with specific exemplary embodiments.

### First Embodiment

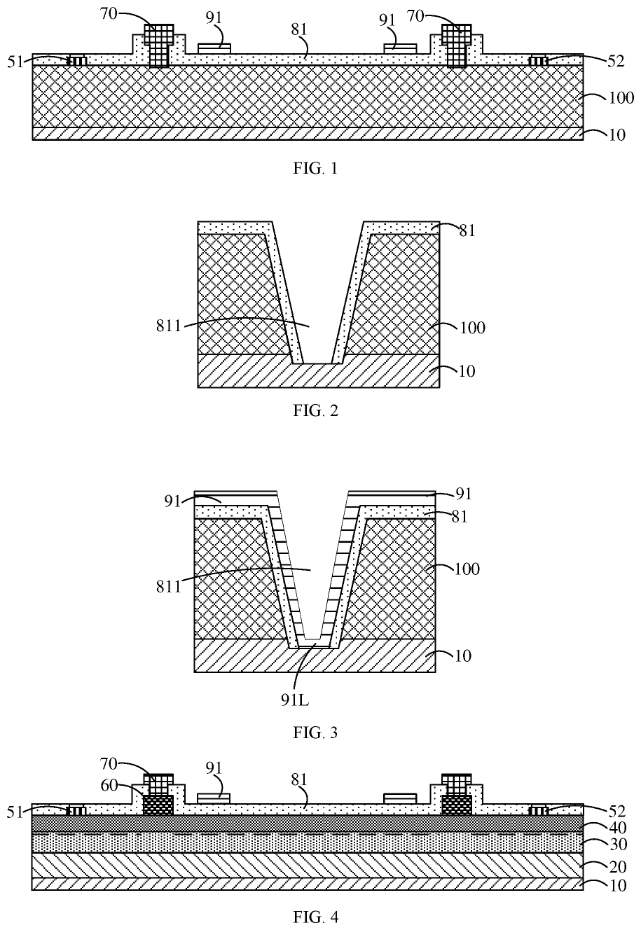

As illustrated in FIGS. 1-3, this embodiment provides a GaN bidirectional switch device, which includes: a substrate 10, a semiconductor epitaxial layer 100, a first-level field plate dielectric layer 81 and two first-level field plate metals 91 (such as a first first-level field plate metal and a second first-level field plate metal).

Specifically, the semiconductor epitaxial layer 100 is disposed on the substrate 10, and the semiconductor epitaxial layer 10 is provided with an active area and a non-active area located outside the active area. The active area is, for example, an area where active components are arranged. The first-level field plate dielectric layer 81 is disposed on a side of the semiconductor epitaxial layer 100 facing away from the substrate 10, and is located in the active area and extends to the non-active area. A groove 811 penetrates the first-level field plate dielectric layer 81 and the semiconductor epitaxial layer 100 to expose a part of the substrate 10, and the groove 811 is located in the non-active area. The groove 811 extends, for example, into the substrate 10 to expose the part of the substrate 10, or extends to a surface of the substrate 10 to expose the part of the substrate 10. The two first-level field plate metals 91 are spaced on a side of the first-level field plate dielectric layer 81 facing away from the semiconductor epitaxial layer 100 and located in the active area, and the two first-level field plate metals 91 are connected through a first interconnecting metal 91L to form a first field plate metal interconnecting structure, and a part of the first field plate metal interconnecting structure is filled in the groove 811 and is connected with the part of the substrate 10 exposed by the groove 811.

The embodiment of the disclosure provides the GaN bidirectional switch device with the above structure, which can avoid using too many power devices and reduce the volume of the GaN bidirectional switch device. In addition, on the one hand, this structure can make the GaN bidirectional switch device have functioning field plates at any time during the AC signal cycle when it is in an off state, so that the electric field distribution in the withstand voltage region is more uniform, and the withstand voltage of the GaN bidirectional switch device can be improved, on the other hand, the structure can also inhibit the electrons in the channel from being captured by defects on the surface or inside of the semiconductor epitaxial layer under the action of a high electric field when the GaN bidirectional switch device is switched from the off state to the on state, so that the on-resistance of the GaN bidirectional switch device is increased when the GaN bidirectional switch device is in the on state, that is, the phenomenon of current collapse is inhibited, and the stability of the GaN bidirectional switch device is further improved.

Alternatively, a material of the first-level field plate dielectric layer 81 includes one or more selected from the group consisting of aluminum nitride (such as AlN), aluminum oxide (such as Al₂O₃), silicon nitride (such as SiNₓ) and silicon oxide (such as SiO₂).

Alternatively, a material of each first-level field plate metal 91 includes one or more selected from the group consisting of nickel (Ni), gold (Au), platinum (Pt), and titanium nitride (TiN). For example, the material of the first-level field plate metal 91 may be a combination of Ni and Au, a combination of Pt and Au, or TiN. Of course, this is only an example. In other embodiments, those skilled in the art can also choose another suitable combination or another feasible material as needed.

Alternatively, for example, there may be one groove 811 or two or more grooves 811.

When the number of the groove 811 is one, for example, as illustrated in FIG. 3, the first interconnecting metal 91L is connected with the first-level field plate metal 91 on the left (for example, the first first-level field plate metal) and the first-level field plate metal 91 on the right (for example, the second first-level field plate metal), and is filled in the groove 811.

When the number of the groove 811 is two (such as a first groove and a second groove), the first interconnecting metal 91L is connected with the first-level field plate metal 91 on the left and the first-level field plate metal 91 on the right, and one of the two grooves 811 (such as the first groove) is located on the left (that is, closer to the first-level field plate metal 91 on the left) and the other of the two grooves 811 (such as the second groove) is located on the right (that is, closer to the first-level field plate metal 91 on the right). That is, the first groove is closer to the first first-level field plate metal than the second groove, and the second groove is closer to the second first-level field plate metal than the first groove. At this time, the first interconnecting metal 91L may be filled in the two grooves 811, or the two first-level field plate metals 91 may be respectively filled in the two grooves 811 close to themselves. For example, the first first-level field plate metal partially fills the first groove and directly contacts the substrate exposed by the first groove, and/or the second first-level field plate metal partially fills the second groove and directly contacts the substrate exposed by the second groove.

When the number of the groove 811 is multiple, the first interconnecting metal 91L is connected with the first-level field plate metal 91 on the left and the first-level field plate metal 91 on the right, and the multiple grooves 811 are distributed on a part of the first interconnecting metal 91L between the two first-level field plate metals 91. At this time, the first interconnecting metal 91L may be filled in the multiple grooves 811. It should be noted that the materials of the first interconnecting metal 91L and the two first-level field plate metals 91 may be the same or different. In this embodiment, the material of the first interconnecting metal 91L is the same as that of the two first-level field plate metals 91, which is convenient for preparation.

The groove 811 may be slotted into the substrate 10, so that the two first-level field plate metals 91 can be connected to the substrate 10 by the groove 811. Specifically, for example, in this embodiment, the first interconnecting metal 91L in the groove 811 is directly connected with the substrate 10.

Furthermore, as illustrated in FIG. 1, the GaN bidirectional switch device further includes: a first electrode 51, a second electrode 52, and two gate electrodes 70 (for example, a first gate electrode and a second gate electrode). The first electrode 51 and the second electrode 52 are located in the active area and are arranged at intervals on the side of the semiconductor epitaxial layer 100 facing away from the substrate 10. The two gate electrodes 70 are located in the active area and arranged at intervals on the side of the semiconductor epitaxial layer 100 facing away from the substrate 10. The first-level field plate dielectric layer 81 covers the first electrode 51, the second electrode 52 and the two gate electrodes 70 and exposes a part of the first electrode 51, a part of the second electrode 51 and parts of the two gate electrodes 70. That is, the first electrode 51, the second electrode 52 and the two gate electrodes 70 are insulated and isolated by the first-level field plate dielectric layer 81.

By adopting the double-gate structure (i.e., two gate electrodes), the GaN bidirectional switch device can share the withstand voltage region in the off state, effectively reducing the overall chip area, thus reducing the system volume of the matrix converter, weakening parasitic effects and improving the system reliability.

In an alternative embodiment of the disclosure, the two gate electrodes 70 are symmetrically arranged between the first electrode 51 and the second electrode 52, for example. The two first-level field plate metals 91 are symmetrically arranged between the two gate electrodes 70.

By using the symmetrically arranged gate electrodes 70 and the symmetrically arranged first-level field plate metals 91, the volume of the device can be further reduced, and the distribution of the withstand voltage region is more uniform when the device is in the off state, thus further improving the withstand voltage of the device.

In an alternative embodiment of the disclosure, as illustrated in FIG. 4, the semiconductor epitaxial layer 100 includes, for example, a buffer layer 20, a channel layer 30, and a barrier layer 40 sequentially formed on the substrate 10. Specifically, the buffer layer 20 is disposed on the substrate 10, the channel layer 30 is disposed on a side of the buffer layer 20 facing away from the substrate 10, and the barrier layer 40 is disposed on a side of the channel layer 30 facing away from the buffer layer 20. The first electrode 51, the second electrode 52, the two gate electrodes 70 and the first-level field plate dielectric layer 81 are disposed on a side of the barrier layer 40 facing away from the channel layer 30.

Of course, the disclosure is not limited to this, and the semiconductor epitaxial layer 100 may also include other layer structures besides the buffer layer 20, the channel layer 30 and the barrier layer 40 mentioned above.

Those skilled in the art can select an appropriate nitride high electron mobility transistor (HEMT) epitaxial structure by themselves and then prepare and form the above-mentioned GaN bidirectional switch device through processing, and the nitride HEMT epitaxial structure includes: the substrate 10 and the semiconductor epitaxial layer 100 formed on the substrate 10. For example, the nitride HEMT epitaxial structure includes: the substrate 10, and the buffer layer 20, the channel layer 30 and the barrier layer 40 which are sequentially formed on the substrate 10.

In an alternative embodiment of the disclosure, as illustrated in FIG. 4, the GaN bidirectional switch device may further include: two P-type nitride layers 60 (for example, a first P-type nitride layer and a second P-type nitride layer), and the two P-type nitride layers 60 correspond to two gate electrodes 70 one by one. The two P-type nitride layers 60 are located between the two gate electrodes 70 and the semiconductor epitaxial layer 100. Specifically, the two P-type nitride layers 60 are located between the two gate electrodes 70 and the barrier layer 40.

The two P-type nitride layers 60 can be prepared by patterning the nitride HEMT epitaxial structure, that is, the nitride HEMT epitaxial structure further includes: the two P-type nitride layers 60.

It should be understood that, as illustrated in FIG. 4, the first electrode 51, the two P-type nitride layers 60 and the second electrode 52 are sequentially spaced from left to right on the barrier layer 40.

In this embodiment, the first electrode 51 and the second electrode 52 are disposed on the barrier layer 40, the first electrode 51 may work in a source operation state and the second electrode 52 may work in a drain operation state. Alternatively, the first electrode 51 may work in the drain operation state and the second electrode 52 may work in the source operation state. The specific operation states of the first electrode 51 and the second electrode 52 can be selected according to actual demand.

In an alternative embodiment of the disclosure, as illustrated in FIG. 5, the GaN bidirectional switch device further includes: an insulating layer 95 disposed between a sidewall of the groove 811 and the first field plate metal interconnecting structure filled in the groove 811.

The insulating layer 95 is used to conduct metal insulation between the first field plate metal interconnecting structure and the semiconductor epitaxial layer, for example, to make the two first-level field plate metals 91 and the first interconnecting metal 91L of the first field plate metal interconnecting structure conduct metal insulation with the buffer layer 20, the channel layer 30 and the barrier layer 40.

For example, the above-mentioned insulating layer 95 may be an insulating layer arranged in the groove 811 alone, or it may be a part of the first-level field plate dielectric layer 81.

When the insulating layer 95 is an insulating layer arranged in the groove 811 alone, that is, it is not the part of the first-level field plate dielectric layer 81, the insulating layer 95 may be formed on the sidewall of the groove 811 after the groove 811 is formed.

When the insulating layer 95 is the part of the first-level field plate dielectric layer 81, the groove 811 can be recessed from the barrier layer 40 toward the substrate 10, and then the first-level field plate dielectric layer 81 can be formed on the barrier layer 40 so that the first-level field plate dielectric layer 81 covers the sidewall and the bottom of the groove 811, and then the substrate 10 can be exposed from the first-level field plate dielectric layer 81 by etching the first-level field plate dielectric layer 81. In this way, the part of the first-level field plate dielectric layer 81 is located on the barrier layer 40, and the other part of the first-level field plate dielectric layer 81 is located on the sidewall of the groove 811.

To sum up, the GaN bidirectional switch device provided in this embodiment includes: the substrate 10, the buffer layer 20, the channel layer 30, the barrier layer 40, and the first electrode 51 and the second electrode 52 arranged on the barrier layer 40 at intervals. The GaN bidirectional switch device also includes: the two gate electrodes 70 arranged at intervals between the first electrode 51 and the second electrode 52, and the first-level field plate dielectric layer 81 formed on the barrier layer 40. The first electrode 51, the second electrode 52 and the two gate electrodes 70 are insulated and isolated by the first-level field plate dielectric layer 81. The first-level field plate dielectric layer 81 defines the groove 811 outside the active area and from the side facing away from the substrate 10. The groove 811 extends from the first-level field plate dielectric layer 81 to the substrate 10 and exposes the substrate 10. The GaN bidirectional switch device further includes: the two first-level field plate metals 91 connected by the first interconnecting metal 91L, so that the first interconnecting metal 91L and the two first-level field plate metals 91 form the first field plate metal interconnecting structure, and the part of the first field plate metal interconnecting structure is filled in the groove 811, and the insulating layer 95 is arranged between the first field plate metal interconnecting structure in the groove 811 and the sidewall of the groove 811. Thus, the GaN bidirectional switch device provided in this embodiment adopts the structure of two gate electrodes 70, which can share the withstand voltage region when it is in the off state, thereby effectively reducing the overall chip area, reducing the system volume of the matrix converter, weakening the parasitic effect and improving the system reliability. At the same time, the GaN bidirectional switch device provided in this embodiment adopts the field plate structure design (for example, two first-level field plate metals 91), on the one hand, the GaN bidirectional switch device has functioning field plates at any time during an AC signal cycle when in an off state, so as to make the electric field distribution in the withstand voltage region more uniform, thereby improving the withstand voltage of the GaN bidirectional switch device, on the other hand, the GaN bidirectional switch device can also inhibit capture of electrons in channels by defects on a surface or in an interior of the barrier layer 40 or buffer layer 20 under the action of a high electric field during switching of the GaN bidirectional switch device from the off state to the on state, so that the on-resistance of the GaN bidirectional switch device in the on state increases, i.e., inhibiting the phenomenon of current collapse, and thus improving the stability of the GaN bidirectional switch device.

### Second Embodiment

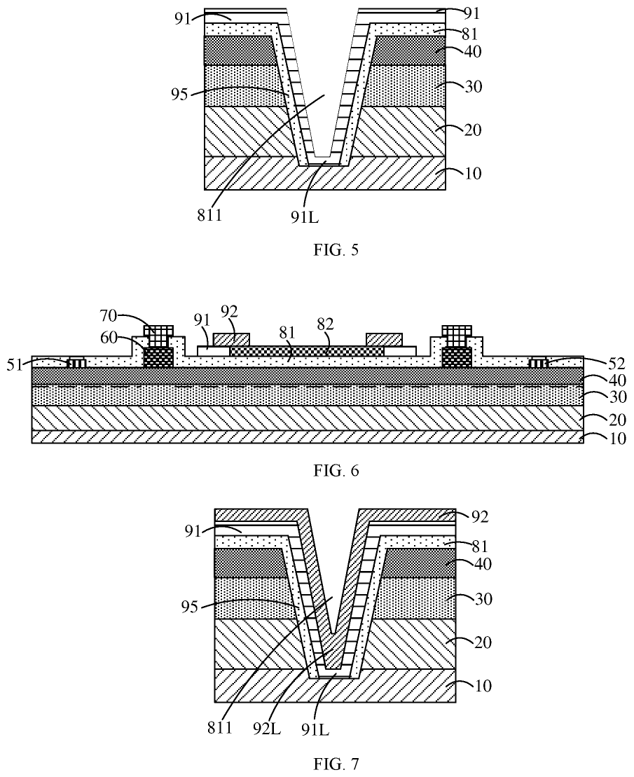

As illustrated in FIG. 6, a GaN bidirectional switch device provided in this embodiment is basically the same as the GaN bidirectional switch device provided by the first embodiment, with the following differences.

The GaN bidirectional switch device of this embodiment further includes: a second-level field plate dielectric layer 82 formed on the first-level field plate dielectric layer 81 and located between the two first-level field plate metals 91.

A material of the second-level field plate dielectric layer 82 may include one or more selected from the group consisting of aluminum nitride (such as AlN), aluminum oxide (such as Al₂O₃), silicon nitride (such as SiNₓ) and silicon oxide (such as SiO₂).

Furthermore, please refer to FIGS. 6 and 7, the GaN bidirectional switch device further includes, for example, two second-level field plate metals 92 (such as a first second-level field plate metal and a second second-level field plate metal) and a second interconnecting metal 92L connected between the two second-level field plate metals 92. The two second-level field plate metals 92 and the connected second interconnecting metal 92L form a second field plate metal interconnecting structure.

The two second-level field plate metals 92 and the two first-level field plate metals 91 are connected in one-to-one correspondence. As illustrated in FIG. 6, the second-level field plate metal 92 on the left (such as the first second-level field plate metal) is connected with the first-level field plate metal 91 on the left (such as the first first-level field plate metal), and the second-level field plate metal 92 on the right (such as the second second-level field plate metal) is connected with the first-level field plate metal 91 on the right (such as the second first-level field plate metal). Meanwhile, the first-level field plate metal 91 on the left and the first-level field plate metal 91 on the right are also connected, while the second-level field plate metal 92 on the left is also connected with the second-level field plate metal 92 on the right. In this way, the two field plates on the left and the two field plates on the right are connected with each other.

In addition, in other embodiments of the disclosure, the first-level field plate metals 91 and the second-level field plate metals 92 may not be directly overlapped together as illustrated in FIG. 6, that is, a field plate dielectric layer may be arranged between the first-level field plate metals 91 and the second-level field plate metals 92 to separate the first-level field plate metals 91 from the second-level field plate metals 92.

It should be noted that the second-level field plate metals 92 and the first-level field plate metals 91 may be the same metal, and they can be formed at the same time during preparation. In addition, the second interconnecting metal 92L may be the same metal as the second-level field plate metals 92.

In an alternative embodiment of the disclosure, as illustrated in FIG. 7, a part of the second field plate metal interconnecting structure is filled in the groove 811. For example, the second interconnecting metal 92L is filled in the groove 811 or the second-level field plate metal 92 is filled in the groove 811, or the second interconnecting metal 92L and the second-level field plate metal 92 all are filled in the groove 811.

In an alternative embodiment of the disclosure, as illustrated in FIG. 7, the second field plate metal interconnecting structure filled in the groove 811 is located on a side of the first field plate metal interconnecting structure filled in the groove 811 facing away from the substrate 10 and is not in contact with the substrate 10. For example, the first interconnecting metal 91L of the first field plate metal interconnecting structure is filled in the groove 811 and is in direct contact with the substrate 10, and the second interconnecting metal 92L of the second field plate metal interconnecting structure is filled in the groove 811, and is disposed on the first interconnecting metal 91L and is not in direct contact with the substrate 10.

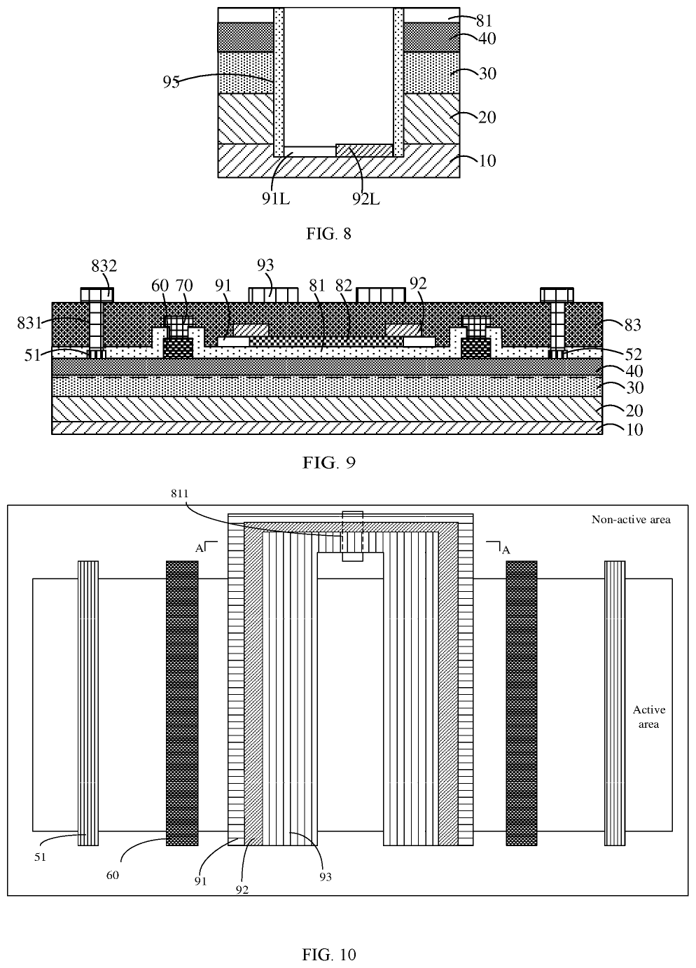

In another alternative embodiment of the disclosure, as illustrated in FIG. 8, the second field plate metal interconnecting structure filled in the groove 811 is disposed on the side of the first field plate metal interconnecting structure filled in the groove 811 facing from the sidewall of the groove 811, and is in direct contact with the substrate 10. For example, the first interconnecting metal 91L of the first field plate metal interconnecting structure is filled in the groove 811 and is in direct contact with the substrate 10; and the second interconnecting metal 92L of the second field plate metal interconnecting structure is filled in the groove 811, and is located at a side of the first interconnecting metal 91L facing away from the sidewall of the groove 811 and is in direct contact with the substrate 10.

In traditional GaN bidirectional switch devices, field plate structures at all levels are source field plates, that is, field plate metals are all connected with their respective source metals, such as two-level field plate metals on the left are connected with a first electrode and two-level field plate metals on the right are connected with a second electrode. This structure will make the two-level field plate metals on the right connected with the second electrode be at a high level at any time during an AC signal cycle when the device is in the off state (VG1=VG2=0V), such as the first electrode is at a low level (0V) and the second electrode is at a variable high level, so that the two-level field plate metals on the right cannot function, and the electric field distribution between a gate electrode on the right and the two-level field plate metals on the right cannot be adjusted, which affects the device performance. In this embodiment, the two-level field plate metals on the left and the two-level field plate metals on the right are connected together and led out of the active area (i.e., led to the non-active area) of the device, and the groove is formed under the metals by etching, so that the above field plate metals are connected to the substrate and grounded. In this way, when the device is turned off (VG1=VG2=0V) and at any time during the AC signal cycle, such as the first electrode is at a low level (0V) and the second electrode is at a variable high level, the above four field plate metals are always 0V because they are connected with the substrate, thus the electric field distribution between the two gate electrodes can be symmetrically adjusted, without the failure of a group of field plate structures in the above-mentioned traditional GaN bidirectional switch device.

To sum up, the GaN bidirectional switch device provided in this embodiment adopts the structure of double gate electrodes 70, which can share the withstand voltage region when it is in the off state, thus effectively reducing the overall chip area, reducing the system volume of the matrix converter, weakening the parasitic effect and improving the system reliability. At the same time, the GaN bidirectional switch device provided in this embodiment adopts the field plate structure design, on the one hand, the GaN bidirectional switch device has functioning field plates at any time during an AC signal cycle when in an off state, so as to make the electric field distribution in the withstand voltage region more uniform, thereby improving the withstand voltage of the GaN bidirectional switch device, on the other hand, the GaN bidirectional switch device can also inhibit capture of electrons in channels by defects on a surface or in an interior of the barrier layer 40 or buffer layer 20 under the action of a high electric field during switching of the GaN bidirectional switch device from the off state to the on state, so that the on-resistance of the GaN bidirectional switch device in the on state increases, i.e., inhibiting the phenomenon of current collapse, and thus improving the stability of the GaN bidirectional switch device.

In addition, the GaN bidirectional switch device provided in this embodiment is provided with the second-level field plate dielectric layer 82, which is used to increase a distance from the second-level field plate metals 92 to the two-dimensional electron gas, so as to achieve the function of dispersing the peak electric field at corners of the first-level field plate metals 91 by the second-level field plate metals 92.

In addition, the GaN bidirectional switch device provided in this embodiment is provided with the two second-level field plate metals 92 symmetrically arranged on the second-level field plate dielectric layer 82, and the distance from the second-level field plate metals 92 to the two-dimensional electron gas and a distance from the first-level field plate metals 91 to the two-dimensional electron gas are different, and further, according to the symmetrically distributed multi-level field plate design, the withstand voltage of the GaN bidirectional switch device is improved, and the phenomenon of current collapse in the switching process of the GaN bidirectional switch device is inhibited, and the stability of the GaN bidirectional switch device is improved.

### Third Embodiment

As illustrated in FIG. 9, a GaN bidirectional switch device provided in this embodiment is basically the same as the GaN bidirectional switch device provided by the second embodiment, with the following differences.

The GaN bidirectional switch device of this embodiment further includes: a third-level field plate dielectric layer 83 formed on the first-level field plate dielectric layer 81. The third-level field plate dielectric layer 83 covers the second-level field plate dielectric layer 82, the two first-level field plate metals 91, the two second-level field plate metals, and the two gate electrodes 70.

The third-level field plate dielectric layer 83 defines two first through-holes 831 corresponding to the first electrode 51 and the second electrode 52 one by one, the two first through-holes 831 extend into the first-level field plate dielectric layer 81, and a first metal 832 exposed outside the third-level field plate dielectric layer 83 is individually deposited in the two first through-holes 831.

It should be noted that the above two first through-holes 831 are respectively arranged at positions of the third-level field plate dielectric layer 83 corresponding to the first electrode 51 and the second electrode 52, and extend into the first-level field plate dielectric layer 81 to expose the first electrode 51 and the second electrode 52. In this way, through the arrangement of the two first through-holes 831, the first electrode 51 and the second electrode 52 can be exposed out of the third-level field plate dielectric layer 83.

The first metal 832 may be directly connected to the first electrode 51 and the second electrode 52, or may be connected to the first electrode 51 and the second electrode 52 through other metals. For example, the two first through-holes 831 may be filled with another metal such as tungsten (W), copper (Cu), aluminum (Al) or gold by electroplating, and then the first metal 832 may be deposited on the above metal.

For example, a material of the first metal 832 may be TiN, Au, etc., or the first metal 832 may be a laminated layer made of titanium (Ti)/Al/TiN.

In an alternative embodiment of the disclosure, as illustrated in FIGS. 9-11, the GaN bidirectional switch device further includes: two third-level field plate metals 93 (for example, a first third-level field plate metal and a second third-level field plate metal) and a third interconnecting metal 93L connected between the two third-level field plate metals 93.

The two third-level field plate metals 93 and the connected third interconnecting metal 93L form a third field plate metal interconnecting structure. A part of the third field plate metal interconnecting structure is filled in the groove 811.

The third-level field plate metals 93 and the second-level field plate metals 92 are connected. Specifically, as shown in FIG. 9, the third-level field plate metal 93 on the left (i.e., the first third-level field plate metal) is connected with the second-level field plate metal 92 on the left (i.e., the first second-level field plate metal), and the third-level field plate metal 93 on the right (i.e., the second third-level field plate metal) is connected with the second-level field plate metal 92 on the right (i.e., the second second-level field plate metal). Meanwhile, the third-level field plate metal 93 on the left and the third-level field plate metal 93 on the right are also connected. In this way, the three field plates on the left and the three field plates on the right are all connected with each other.

In some embodiments of the disclosure, a thickness of the third-level field plate dielectric layer 83 is, for example, greater than that of the second-level field plate dielectric layer 82, thereby increasing the withstand voltage and MI metal routing, and improving the feasibility of the overall process.

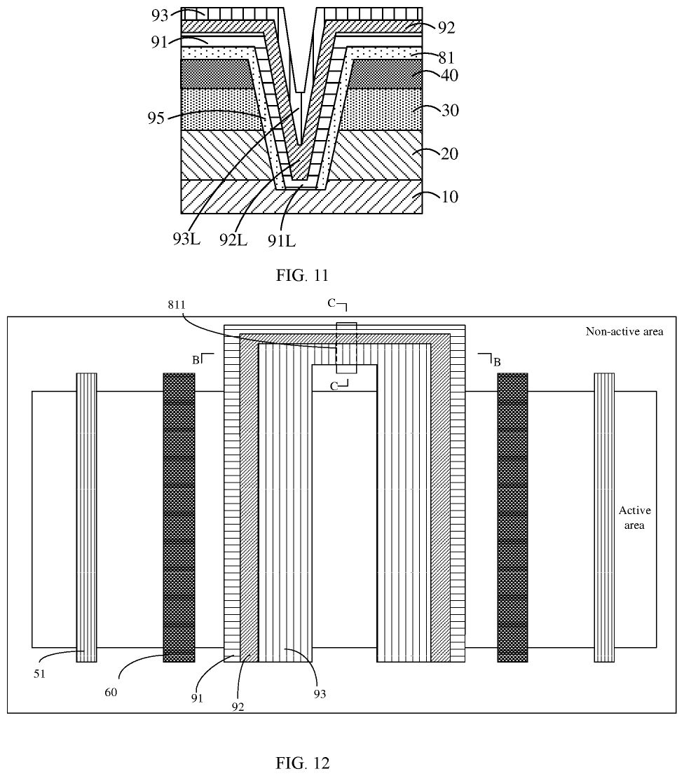

In some embodiments of the disclosure, referring to FIGS. 10 and 11, the first field plate metal interconnecting structure is filled in the groove 811 and is in direct contact with the part of the substrate 10 exposed by the groove 811; the second field plate metal interconnecting structure is filled in the groove 811, and is located on a side of the first field plate metal interconnecting structure facing away from the substrate 10 and is not in contact with the substrate 10; and the third field plate metal interconnecting structure is filled in the groove 811, and is located on a side of the second field plate metal interconnecting structure facing away from the first field plate metal interconnecting structure and is not in contact with the substrate 10. That is, only the first field plate metal interconnecting structure, such as the first interconnecting metal 91L of the first field plate metal interconnecting structure, is in direct contact with the substrate 10 exposed by the groove 811.

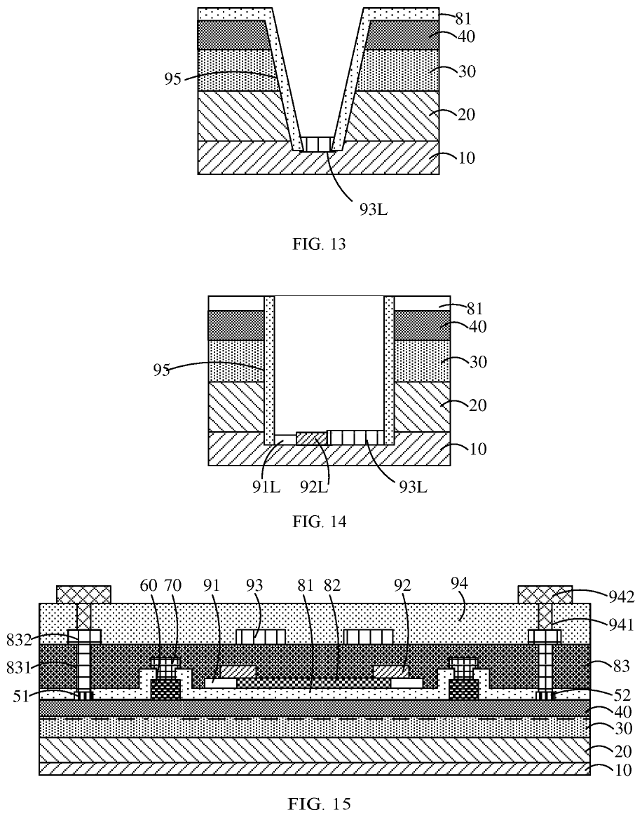

In some embodiments of the disclosure, referring to FIGS. 12, 13 and 14, the first field plate metal interconnecting structure is filled in the groove 811 and is in direct contact with the substrate 10 exposed by the groove 811; the second field plate metal interconnecting structure is filled in the groove 811, is located on a side of the first field plate metal interconnecting structure facing away from a sidewall of the groove 811 and is in direct contact with the substrate 10; and the third field plate metal interconnecting structure is filled in the groove 811, is located between the second field plate metal interconnecting structure and the sidewall of the groove 811, and is in direct contact with the substrate 10. That is, in the groove 811, the first field plate metal interconnecting structure such as the first interconnecting metal 91L of the first field plate metal interconnecting structure, the second field plate metal interconnecting structure such as the second interconnecting metal 92L of the second field plate metal interconnecting structure, and the third field plate metal interconnecting structure such as the third interconnecting metal 93L of the third field plate metal interconnecting structure are all in direct contact with the substrate 10.

In traditional GaN bidirectional switch devices, field plate structures at all levels are source field plates, that is, field plate metals are all connected with their respective source metals, such as three-level field plate metals on the left are connected with a first electrode and three-level field plate metals on the right are connected with a second electrode. This structure will make the three-level field plate metals on the right connected with the second electrode be at a high level at any time during an AC signal cycle when the device is turned off (VG1=VG2=0V), such as the first electrode is at a low level (0V) and the second electrode is at a variable high level, so that the three-level field plate metals on the right connected to the second electrode cannot function, and the electric field distribution between a gate electrode on the right and the three-level field plate metals on the right cannot be adjusted, which affects the device performance. In this embodiment, the three-level field plate metals on the left and the three-level field plate metals on the right are connected together and led out of the active area (i.e., led to the non-active area) of the device, and the groove is formed under the metals by etching, so that the field plate metals are connected to the substrate and grounded. In this way, when the device is turned off (VG1=VG2=0V) and at any time during the AC signal cycle, such as the first electrode is at a low level (0V) and the second electrode is at a variable high level, the above six field plate metals are always 0V because they are connected with the substrate, thus the electric field distribution between the two gate electrodes can be symmetrically adjusted, without the failure of a group of field plate structures in the above-mentioned traditional GaN bidirectional switch device.

To sum up, the GaN bidirectional switch device provided in this embodiment adopts the structure of double gate electrodes 70, which can share the withstand voltage region when it is turned off, thus effectively reducing the overall chip area, thereby reducing the system volume of the matrix converter, weakening the parasitic effect and improving the system reliability. At the same time, the GaN bidirectional switch device provided in this embodiment adopts multi-level field plate structure design, on the one hand, the GaN bidirectional switch device has functioning field plates at any time during an AC signal cycle when in an off state, so as to make the electric field distribution in the withstand voltage region more uniform, thereby improving the withstand voltage of the GaN bidirectional switch device, on the other hand, the GaN bidirectional switch device can also inhibit capture of electrons in channels by defects on a surface or in an interior of the barrier layer 40 or buffer layer 20 under the action of a high electric field during switching of the GaN bidirectional switch device from the off state to the on state, so that the on-resistance of the GaN bidirectional switch device in the on state increases, i.e., inhibiting the phenomenon of current collapse, and thus improving the stability of the GaN bidirectional switch device.

In addition, the GaN bidirectional switch device provided in this embodiment is provided with the two third-level field plate metals 93 symmetrically arranged on the third-level field plate dielectric layer 83, and the distance from the third-level field plate metals 93 to the two-dimensional electron gas, the distance from the second-level field plate metals 92 to the two-dimensional electron gas, and the distance from the first-level field plate metals 91 to the two-dimensional electron gas are different, and further, according to the symmetrically distributed multi-level field plate design, the withstand voltage of the GaN bidirectional switch device is improved, and the phenomenon of current collapse in the switching process of the GaN bidirectional switch device is inhibited, and the stability of the GaN bidirectional switch device is improved.

### Fourth Embodiment

As illustrated in FIG. 15, a GaN bidirectional switch device provided in this embodiment is basically the same as the GaN bidirectional switch device provided by the third embodiment, with the following differences.

The GaN bidirectional switch device of this embodiment further includes: a fourth-level field plate dielectric layer 94. The fourth-level field plate dielectric layer 94 is disposed on a side of the third-level field plate dielectric layer 83 facing away from the first-level field plate dielectric layer 81 and covers the two third-level field plate metals 93.

The fourth-level field plate dielectric layer 94 defines two second through-holes 941 corresponding to the first metal 832 filled in the first through-holes 831, and a second metal 942 connected with the first metal 832 and exposed outside the fourth-level field plate dielectric layer 94 is deposited in the two second through-holes 941.

The two second through-holes 941 are provided to facilitate the first electrode 51 and the second electrode 52 to be exposed out through the second through-holes 941.

The opening mode of the second through-holes 941 and the material of the second metal 942 may refer to the relevant descriptions of the first through-holes 831 and the first metal 832 in the third embodiment. In addition, the second metal 942 and the first metal 832 can be directly connected or connected by another metal. For example, the second through-holes 941 can be filled with another metal such as tungsten, copper, aluminum or gold by electroplating, and then the second metal 942 can be deposited on the above metal.

A schematic diagram of a working state of a GaN bidirectional switch device provided in this embodiment of the disclosure is illustrated in FIG. 17. The GaN bidirectional switch device includes: four working states, that is, the GaN bidirectional switch device works in a bidirectional switch mode and is in the off state, the GaN bidirectional switch device works in the bidirectional switch mode and is in the on state, the GaN bidirectional switch device works in a diode mode and is in the right-to-left turn-on state, and the GaN bidirectional switch device works in the diode mode and is in the left-to-right turn-on state.

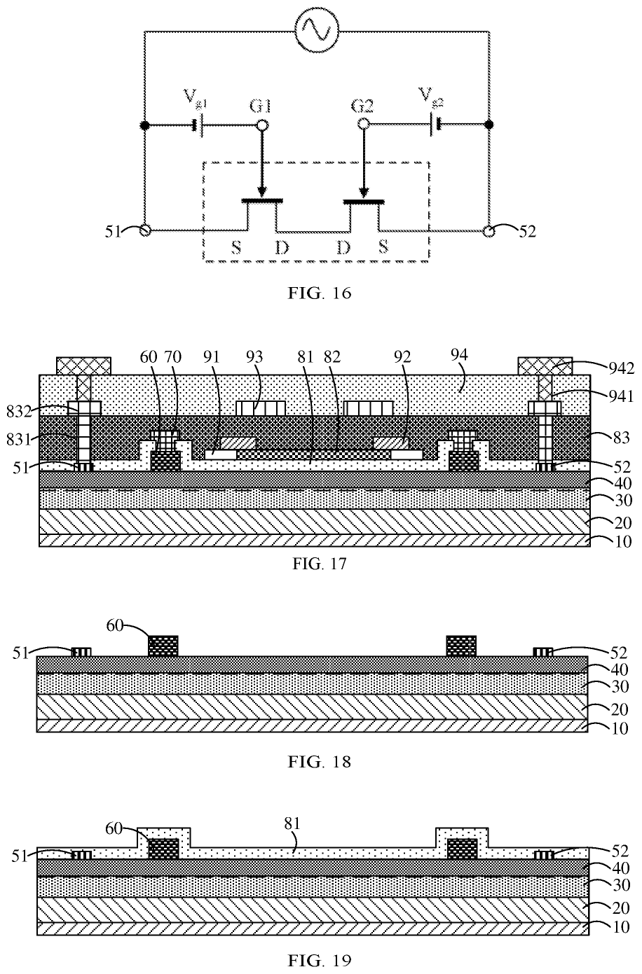

To sum up, the GaN bidirectional switch device provided in this embodiment can share the withstand voltage region in the off state (i.e., VG1=VG2=0V, as illustrated in FIGS. 16 and 17) by adopting the structure of two gate electrodes 70, thus effectively reducing the overall chip area, thereby reducing the system volume of the matrix converter, weakening the parasitic effect and improving the system reliability. At the same time, the GaN bidirectional switch device provided in this embodiment adopts the field plate structure design, on the one hand, the GaN bidirectional switch device has functioning field plates at any time during an AC signal cycle when in an off state, so as to make the electric field distribution in the withstand voltage region more uniform, thereby improving the withstand voltage of the GaN bidirectional switch device, on the other hand, the GaN bidirectional switch device can also inhibit capture of electrons in channels by defects on a surface or in an interior of the barrier layer 40 or buffer layer 20 under the action of a high electric field during switching of the GaN bidirectional switch device from the off state to the on state, so that the on-resistance of the GaN bidirectional switch device in the on state increases, i.e., inhibiting the phenomenon of current collapse, and thus improving the stability of the GaN bidirectional switch device.

It is worth mentioning that the disclosure does not limit the number of field plate metals included in the GaN bidirectional switch device, for example, the GaN bidirectional switch device may include N-level field plate metals, where N is a positive integer greater than 0. In addition, the disclosure also does not limit the number of field plate dielectric layers included in the GaN bidirectional switch device and the number of field plate dielectric layers can be set according to the N-level field plate metals and the actual situation.

### Fifth Embodiment

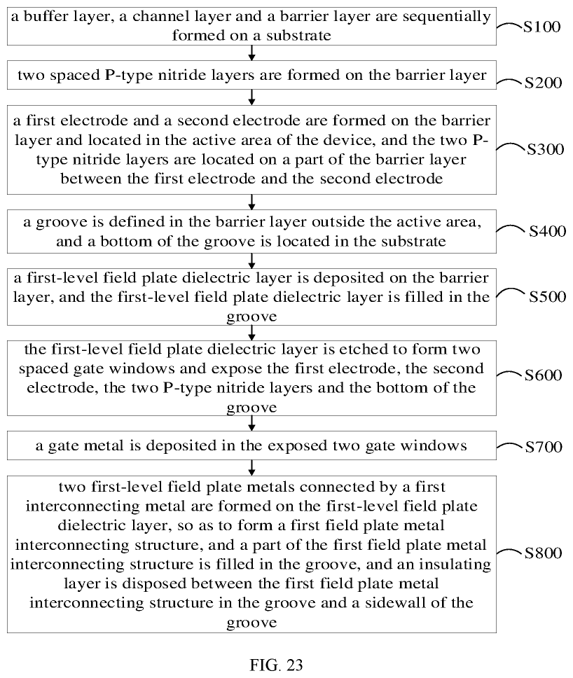

Referring to FIGS. 18 to 23, this embodiment provides a method for preparing a GaN bidirectional switch device, which includes the following steps.

S100, a buffer layer 20, a channel layer 30 and a barrier layer 40 are sequentially formed on a substrate 10.

S200, two spaced P-type nitride layers 60 are formed on the barrier layer 40.

It should be noted that, specifically, the above step S200 may include: forming a whole P-type nitride layer 60 on the barrier layer 40, and then etching the P-type nitride layer 60 to form the two P-type nitride layers 60 arranged at intervals.

When the P-type nitride layers 60 are not needed in the GaN bidirectional switch device, those skilled in the art may choose not to perform the above step S200 according to the actual demand.

S300, a first electrode 51 and a second electrode 52 are formed on the barrier layer 40 and located in the active area of the device, and the two P-type nitride layers 60 are located on a part of the barrier layer 40 between the first electrode 51 and the second electrode 52, as illustrated in FIG. 18.

The first electrode 51 and the second electrode 52 can be prepared by electron beam evaporation or magnetron sputtering.

In addition, metal systems of the first electrode 51 and the second electrode 52 may include Ti/Al/Ni/Au (i.e., a stacked layer made of Ti, Al, Ni and Au), or Ti/Al/Ti/Au (i.e., a stacked layer made of Ti, Al, Ti and Au), or Ti/Al/TiN (i.e., a stacked layer made of Ti, Al, TiN). Of course, it should be understood that the above-mentioned metal systems of the first electrode 51 and the second electrode 52 are only examples, and are not limitations on the metal systems of the first electrode 51 and the second electrode 52. Those skilled in the art can also select other suitable metal systems as required.

S400, a groove 811 is defined in the barrier layer 40 outside the active area, and a bottom of the groove 811 is located in the substrate 10, as illustrated in FIG. 22.

A groove 811 is defined on the barrier layer 40 outside the active area, and the bottom of the groove 811 is located in the substrate 10, that is, the groove 811 extends from a surface of the barrier layer 40 facing away from the substrate 10 to the substrate 10, and the groove 811 extends into the substrate 10. Similar to the GaN bidirectional switch devices described above, the number of the groove 811 may be one, two, or more. The specific situation has been described in detail in the foregoing and will not be repeated here.

S500, a first-level field plate dielectric layer 81 is deposited on the barrier layer 40, and the first-level field plate dielectric layer 81 is filled in the groove 811.

Please refer to FIG. 19 and FIG. 22, a part of the first-level field plate dielectric layer 81 is located on the barrier layer 40, and the other part of the first-level field plate dielectric layer 81 is located in the groove 811.

The deposition equipment for depositing the first-level field plate dielectric layer 81 can be an atomic layer deposition (ALD) device, a plasma enhanced chemical vapor deposition (PECVD) device or a low pressure chemical vapor deposition (LPCVD) device.

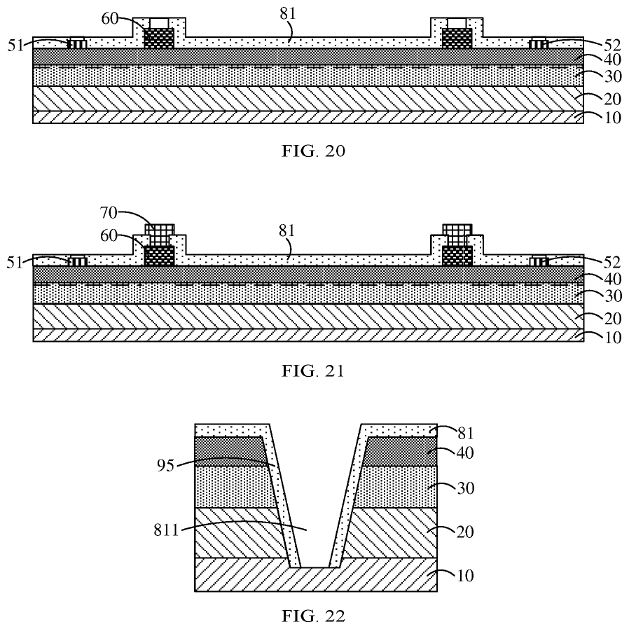

S600, the first-level field plate dielectric layer 81 is etched to form two spaced gate windows and expose the first electrode 51, the second electrode 52, the two P-type nitride layers 60 and the bottom of the groove 811, as illustrated in FIGS. 20 and 22.

As illustrated in FIG. 22, after etching the first-level field plate dielectric layer 81, the part of the first-level field plate dielectric layer 81 located at the bottom of the groove 811 is removed, so that the subsequent connection of first-level field plate metals 91 with the substrate 10 can be facilitated.

When the two P-type nitride layers 60 are not needed for the GaN bidirectional switch device to be prepared, the above step S600 is: etching the first-level field plate dielectric layer 81 to form two spaced gate windows and expose the first electrode 51, the second electrode 52 and the bottom of the groove 811. The gate windows are the corresponding hole positions for the subsequent deposition of the metal of the gate electrodes.

S700, a gate metal is deposited in the exposed two gate windows, as illustrated in FIG. 21.

S800, two first-level field plate metals 91 connected by a first interconnecting metal 91L are formed on the first-level field plate dielectric layer 81, so as to form a first field plate metal interconnecting structure, and a part of the first field plate metal interconnecting structure, such as the first interconnecting metal 91L, is filled in the groove 811, and an insulating layer 95, such as a part of the first-level field plate dielectric layers 81, is disposed between the first interconnecting metal 91L in the groove 811 and a sidewall of the groove 811.

In this way, the above GaN bidirectional switch device with one-level field plate structure (for example, including two first-level field plate metals 91 symmetrically arranged) can be obtained, as shown in FIG. 4. The method for preparing the GaN bidirectional switch device provided in this embodiment is simple, and the GaN bidirectional switch device with small device volume, more uniform distribution of the withstand voltage region and more withstand voltage can be obtained when the device is in the off state.

In addition, after performing the above step S800, this embodiment further includes: forming two symmetrical second-level field plate metals 92 on the two first-level field plate metals 91, and the distance between the two second-level field plate metals 92 and the two-dimensional electron gas is greater than the distance between the two first-level field plate metals 91 and the two-dimensional electron gas. It should be noted that the second-level field plate metals 92 and the first-level field plate metals 91 may be the same metal, and they may be formed at the same time during preparation. For example, a second-level field plate dielectric layer 82 may be formed before the step S800 is performed, and then the second-level field plate metals 92 may be formed together when the step S800 is performed to form the first-level field plate metals 91, for example, the GaN bidirectional switch device as illustrated in FIG. 6 is formed.

After forming the two symmetrical second-level field plate metals 92, this embodiment may further include: forming two symmetrical third-level field plate metals 93 on the two second-level field plate metals 92. The distance between the two third-level field plate metals 93 and the two-dimensional electron gas is greater than the distance between the two second-level field plate metals 92 and the two-dimensional electron gas, for example, the GaN bidirectional switch device as illustrated in FIG. 9 is formed.

The preparation methods of the above two second-level field plate metals 92 and two third-level field plate metals 93 are derived by those skilled in the art by referring to the preparation methods of the above two first-level field plate metals 91 and the brief descriptions of the second-level field plate metals 92 and the third-level field plate metals 93 in the above embodiments, so they are not described here.

The foregoing is only the optional embodiment of the disclosure and is not intended to limit the disclosure, which may be subject to various changes and variations for those skilled in the art. Any modifications, equivalent substitutions, improvements, etc. made within the spirit and principles of the disclosure shall be included in the scope of protection of the disclosure.

It is also to be noted that the various specific technical features described in the above specific embodiments may be combined in any suitable manner without contradiction, and in order to avoid unnecessary repetitions, the disclosure will not be separately described with respect to the various possible combinations.

What is claimed is:

1. A gallium nitride (GaN) bidirectional switch device, comprising:
a substrate;
a semiconductor epitaxial layer, disposed on the substrate; wherein the semiconductor epitaxial layer is provided with an active area and a non-active area located outside the active area;
a first-level field plate dielectric layer, disposed on a side of the semiconductor epitaxial layer facing away from the substrate; wherein the first-level field plate dielectric layer is located in the active area and extends to the non-active area;
a groove, penetrating the first-level field plate dielectric layer and the semiconductor epitaxial layer to expose a part of the substrate; wherein the groove is located in the non-active area; and
a first first-level field plate metal and a second first-level field plate metal, spaced on a side of the first-level field plate dielectric layer facing away from the semiconductor epitaxial layer and located in the active area; wherein the first first-level field plate metal and the second first-level field plate metal are connected through a first interconnecting metal to form a first field plate metal interconnecting structure, and a part of the first field plate metal interconnecting structure is filled in the groove and is connected with the part of the substrate exposed by the groove.

2. The GaN bidirectional switch device as claimed in claim 1, wherein the GaN bidirectional switch device further comprises:
a first electrode and a second electrode, located in the active area and spaced on the side of the semiconductor epitaxial layer facing away from the substrate; and
a first gate electrode and a second gate electrode, located in the active area and spaced on the side of the semiconductor epitaxial layer facing away from the substrate; wherein the first gate electrode and the second gate electrode are symmetrically arranged between the first electrode and the second electrode;
wherein the first-level field plate dielectric layer covers the first electrode, the second electrode, the first gate electrode and the second gate electrode and exposes a part of the first electrode, a part of the second electrode, a part of the first gate electrode and a part of the second gate electrode; and
wherein the first first-level field plate metal and the second first-level field plate metal are symmetrically arranged between the first gate electrode and the second gate electrode.

3. The GaN bidirectional switch device as claimed in claim 1, wherein a part of the first-level field plate dielectric layer extends into the groove to act as an insulating layer, and the insulating layer is disposed between a sidewall of the groove and the part of the first field plate metal interconnecting structure filled in the groove.

4. The GaN bidirectional switch device as claimed in claim 1, wherein the GaN bidirectional switch device further comprises:
an insulating layer, disposed between a sidewall of the groove and the part of the first field plate metal interconnecting structure filled in the groove.

5. The GaN bidirectional switch device as claimed in claim 2, wherein the semiconductor epitaxial layer comprises:
a buffer layer, disposed on the substrate;
a channel layer, disposed on a side of the buffer layer facing away from the substrate; and
a barrier layer, disposed on a side of the channel layer facing away from the buffer layer;
wherein the first electrode, the second electrode, the first gate electrode, the second gate electrode and the first-level field plate dielectric layer are disposed on a side of the barrier layer facing away from the channel layer.

6. The GaN bidirectional switch device as claimed in claim 2, wherein the GaN bidirectional switch device further comprises: a first P-type nitride layer and a second P-type nitride layer; and the first P-type nitride layer is disposed between the first gate electrode and the semiconductor epitaxial layer, and the second P-type nitride layer is disposed between the second gate electrode and the semiconductor epitaxial layer.

7. The GaN bidirectional switch device as claimed in claim 1, wherein a part of the first interconnecting metal of the first field plate metal interconnecting structure is filled in the groove and is in direct contact with the part of the substrate exposed by the groove.

8. The GaN bidirectional switch device as claimed in claim 1, wherein the groove comprises: a first groove and a second groove; the first groove is closer to the first first-level field plate metal than the second groove, and the second groove is closer to the second first-level field plate metal than the first groove, and a part of the first first-level field plate metal of the first field plate metal interconnecting structure is filled in the first groove and is in direct contact with a part of the substrate exposed by the first groove.

9. The GaN bidirectional switch device as claimed in claim 8, wherein a part of the second first-level field plate metal of the first field plate metal interconnecting structure is filled in the second groove and is in direct contact with a part of the substrate exposed by the second groove.

10. The GaN bidirectional switch device as claimed in claim 1, wherein the GaN bidirectional switch device further comprises:
a second-level field plate dielectric layer, disposed on a side of the first-level field plate dielectric layer facing away from the semiconductor epitaxial layer and located between the first first-level field plate metal and the second first-level field plate metal.

11. The GaN bidirectional switch device as claimed in claim 10, wherein the GaN bidirectional switch device further comprises:
a first second-level field plate metal, disposed on a side of the first first-level field plate metal facing away from the first-level field plate dielectric layer and connected with the first first-level field plate metal;
a second second-level field plate metal, disposed on a side of the second first-level field plate metal facing away from the first-level field plate dielectric layer and connected with the second first-level field plate metal; and
a second interconnecting metal, connected with the first and second second-level field plate metals to form a second field plate metal interconnecting structure.

12. The GaN bidirectional switch device as claimed in claim 11, wherein a part of the second field plate metal interconnecting structure is filled in the groove.

13. The GaN bidirectional switch device as claimed in claim 12, wherein the part of the second field plate metal interconnecting structure filled in the groove is disposed on a side of the part of the first field plate metal interconnecting structure filled in the groove facing away from the substrate and is not in contact with the substrate.

14. The GaN bidirectional switch device as claimed in claim 12, wherein the part of the second field plate metal interconnecting structure filled in the groove is disposed on a side of the part of the first field plate metal interconnecting structure filled in the groove facing away from a sidewall of the groove, and is in direct contact with the substrate.

15. The GaN bidirectional switch device as claimed in claim 11, wherein the GaN bidirectional switch device further comprises:
a third-level field plate dielectric layer, disposed on the first-level field plate dielectric layer and covering the second-level field plate dielectric layer, the first first-level field plate metal, the second first-level field plate metal, the first second-level field plate metal and the second second-level field plate metal.

16. The GaN bidirectional switch device as claimed in claim 15, wherein the GaN bidirectional switch device further comprises:
a first third-level field plate metal, disposed on a side of the third-level field plate dielectric layer facing away from the first-level field plate dielectric layer and connected with the first second-level field plate metal;
a second third-level field plate metal, disposed on the side of the third-level field plate dielectric layer facing away from the first-level field plate dielectric layer and connected with the second second-level field plate metal; and
a third interconnecting metal, connected with the first and second third-level field plate metals to form a third field plate metal interconnecting structure.

17. The GaN bidirectional switch device as claimed in claim 16, wherein a part of the third field plate metal interconnecting structure is filled in the groove.

18. The GaN bidirectional switch device as claimed in claim 17, wherein the part of the third field plate metal interconnecting structure filled in the groove is disposed on a side of the part of the second field plate metal interconnecting structure filled in the groove facing away from the part of the first field plate metal interconnecting structure filled in the groove, and is not in contact with the substrate.

19. The GaN bidirectional switch device as claimed in claim 17, wherein the part of the third field plate metal interconnecting structure filled in the groove is disposed between the part of the second field plate metal interconnecting structure filled in the groove and a sidewall of the groove, and is in direct contact with the substrate.

20. The GaN bidirectional switch device as claimed in claim 16, wherein the GaN bidirectional switch device further comprises:
a fourth-level field plate dielectric layer, disposed on a side of the third-level field plate dielectric layer facing away from the first-level field plate dielectric layer and covering the first third-level field plate metal and the second third-level field plate metal.
